(19) United States
(12) Patent Application Publication
(10) Pub. No.: US 2015/0213924 A1
(43) Pub. Date: Jul. 30, 2015

(54) FLEXIBLE FLAT CABLE

(71) Applicant: Wei Sun Chang, Taipei City (TW)

(72) Inventor: Wei Sun Chang, Taipei City (TW)

(21) Appl. No.: 14/607,210

(22) Filed: Jan. 28, 2015

(30) Foreign Application Priority Data
Jan. 28, 2014 (TW) 103201813

(51) Int. Cl. H01B 7/08; H05K 9/00; H01B 7/18

(52) U.S. Cl. CPC H01B 7/0869; H01B 7/1875; H05K 9/0098

(57) ABSTRACT

A flexible flat cable is described. The flexible flat cable is formed by sequentially stacking a first insulation layer, a first shielding layer and a second insulation layer. The first insulation layer covers a plurality of first conductors and the second insulation layer covers a plurality of second conductors. The first contact surface region of the first conductors is upwardly exposed from the first contact section and the second contact surface region of the second conductors is downwardly exposed from the second contact section so that the flexible flat cable, the first contact section and the second contact section thereof are arranged in a dual-row manner.

### BACKGROUND OF THE INVENTION

1. Field of Invention

The present invention relates to a flexible flat cable, and more particularly to a flexible flat cable with a laminated construction including stacked first insulation layer, first shielding layer and second insulation layer sequentially wherein a first contact section and a second contact section are formed in one end portion of the flexible flat cable, and the flexible flat cable, the first contact section and the second contact section thereof are arranged in a dual-row manner.

2. Description of Prior Art

Conventionally, Taiwan Patent No. M413241 entitled “Electrical connector assembly having a printed circuit board with soldering holes interconnected to a plurality of contacts” (also published as China Patent No. CN202503124U and U.S. Pat. No. 8,512,071) disclosed a connector assembly. The connector assembly is provided with an insulating housing, a plurality of data and power terminals, a printed circuit board (PCB) and a flexible flat cable (FFC), wherein the data and power terminals inserted in the insulating housing, the PCB secured to the insulating housing, the FFC soldered on the PCB, the data and power terminals are electrically interconnected the FFC by the PCB. The provision of the unitary construction feature of FFC can save the production cost due to its eliminating cable management equipment and the step of cable managing processes. However, the conventional FFC is constructed by a single-row arrangement to form a larger width and there is a need to enhance the structural strength of FFC.

### SUMMARY OF THE INVENTION

To solve the aforementioned problems, one objective of the present invention is to provide a flexible flat cable. The flexible flat cable is formed by sequentially stacking a first insulation layer, a first shielding layer and a second insulation layer. The first insulation layer covers a plurality of first conductors and the second insulation layer covers a plurality of second conductors. The first contact surface region of the first conductors is upwardly exposed from the first contact section and the second contact surface region of the second conductors is downwardly exposed from the second contact section.

Another objective of the present invention is to provide a flexible flat cable. A first insulation layer and a second insulation layer are formed by bending an insulation layer. A first shielding layer disposed between the first insulation layer and the second insulation layer so that the first insulation layer, the first shielding layer and the second insulation layer are sequentially stacked to form the flexible flat cable. The first insulation layer covers a plurality of first conductors and a second insulation layer covers a plurality of second conductors wherein the first contact surface region of the first conductors is upwardly exposed from the first contact section, and the second contact surface region of the second conductors is downwardly exposed from the second contact section.

In the present invention, the flexible flat cable comprises a first insulation layer, covering a plurality of first conductors and comprising a first contact section in a front end of the first insulation layer wherein the first contact section exposes a first contact surface region of the first conductors; a second insulation layer, covering a plurality of second conductors and comprising a second contact section in the front end of the second insulation layer wherein the second contact section exposes a second contact surface region of the second conductors; and a first shielding layer disposed between the first insulation layer and the second insulation layer, wherein the first contact surface region of the first conductors is upwardly exposed from the first contact section and the second contact surface region of the second conductors is downwardly exposed from the second contact section.

In one embodiment, the first insulation layer comprises another first contact section in a rear end of the first insulation layer, another first contact surface region of the first conductors is upwardly exposed from the first contact section in the rear end of the first insulation layer, the second insulation layer comprises another second contact section in the rear end of the second insulation layer, and a second contact surface region of the second conductors is downwardly exposed from the second contact section in the rear end of the second insulation layer.

In one embodiment, the first shielding layer extends to an in-between position of the first contact section and the second contact section to improve construction strength and shielding effect of the flexible flat cable.

In one embodiment, a first insulation supporting plate is disposed in an in-between position of the first contact section and the second contact section to improve the construction strength and shielding effect of the flexible flat cable.

In one embodiment, a second insulation supporting plate is disposed in the in-between position of the first contact section and the second contact section to improve the construction strength and shielding effect of the flexible flat cable.

In one embodiment, a second shielding layer is disposed between the first shielding layer and the second insulation layer, and material of the first shielding layer and the second shielding layer is selected from one group consisting of aluminum foil, polytetrafluoroethylene (Teflon), acetate cloth insulating tape and material with electromagnetic shielding effect.

In one embodiment, a third shielding layer further covers an outer surface of a main body section of the flexible flat cable and is material selecting from one group consisting of aluminum foil, polytetrafluoroethylene (Teflon), acetate cloth insulating tape and the material with electromagnetic shielding effect.

In one embodiment, either the first conductors and the second conductors are interlaced upward and downward or the first conductors and the second conductors are disposed correspondingly upward and downward.

In the present invention, the flexible flat cable comprises an insulation layer, for being bent to form a first insulation layer and a second insulation layer; a plurality of first conductors, for covering the first insulation layer wherein a first contact surface region of the first conductors is exposed from a first contact section of the first insulation layer; a plurality of second conductors, for covering the second insulation layer wherein a second contact surface region of the second conductors is exposed from the second contact section; and a first shielding layer disposed between the first insulation layer and the second insulation layer, wherein the first contact surface region of the first conductors is upwardly exposed from the first contact section and the second contact surface region of the second conductors is downwardly exposed from the second contact section.

In one embodiment, the first insulation layer comprises another first contact section in a rear end of the first insulation layer, another first contact surface region of the first conductors is upwardly exposed from the first contact section in the rear end of the first insulation layer, the second insulation layer comprises another second contact section in the rear end of the second insulation layer, and a second contact surface region of the second conductors is downwardly exposed from the second contact section in the rear end of the second insulation layer.

In one embodiment, the first shielding layer extends to an in-between position of the first contact section and the second contact section to improve a construction strength and shielding effect of the flexible flat cable.

In one embodiment, a first insulation supporting plate is disposed in an in-between position of the first contact section and the second contact section to improve the construction strength and shielding effect of the flexible flat cable.

In one embodiment, a second insulation supporting plate is disposed in the in-between position of the first contact section and the second contact section, and the first insulation supporting plate and the second insulation supporting plate are formed by bending an identical insulation supporting plate.

In one embodiment, a second shielding layer is disposed between the first shielding layer and the second insulation layer, the first shielding layer and the second shielding layer are formed by bending an identical shielding layer, and material of the first shielding layer and the second shielding layer is selected from one group consisting of aluminum foil, polytetrafluoroethylene (Teflon), acetate cloth insulating tape and material with electromagnetic shielding effect.

In one embodiment, a third shielding layer further covers an outer surface of a main body section of the flexible flat cable and is material selecting from one group consisting of aluminum foil, polytetrafluoroethylene (Teflon), acetate cloth insulating tape and the material with electromagnetic shielding effect.

In one embodiment, either the first conductors and the second conductors are interlaced upward and downward or the first conductors and the second conductors are disposed correspondingly upward and downward.

In the present invention, the flexible flat cable comprises a first insulation layer, covering a plurality of first conductors and comprising a first contact section in a front end of the first insulation layer wherein the first contact section exposes a first contact surface region of the first conductors; and a second insulation layer, covering a plurality of second conductors and comprising a second contact section in the front end of the second insulation layer, wherein the second contact section exposes a second contact surface region of the second conductors; wherein the first contact surface region of the first conductors is upwardly exposed from the first contact section, and the second contact surface region of the second conductors is downwardly exposed from the second contact section; and wherein a vertical distance between the first conductors and the second conductors is greater than twice a thickness of either the first conductor or the second conductor.

In one embodiment, the first insulation layer comprises another first contact section in a rear end of the first insulation layer, another first contact surface region of the first conductors is upwardly exposed from the first contact section in the rear end of the first insulation layer, the second insulation layer comprises another second contact section in the rear end of the second insulation layer, and a second contact surface region of the second conductors is downwardly exposed from the second contact section in the rear end of the second insulation layer.

In one embodiment, the first insulation layer is glued to the second insulation layer, and the first insulation layer and the second insulation layer are an individual insulation layer respectively.

In one embodiment, the first conductors and the second conductors are interlaced upward and downward or the first conductors and the second conductors are disposed correspondingly upward and downward.

The advantage of the present invention is that the flexible flat cable employs laminated construction in a dual-row manner to reduce the width of flexible flat cable as a whole. Furthermore, the first insulation layer, the first shielding layer and the second shielding layer are sequentially stacked to enhance the whole strength of the flexible flat cable. In addition, since the first contact surface region of the first conductors is upwardly exposed from the first contact section and the second contact surface region of the second conductors is downwardly exposed from the second contact section, it is beneficial that the flexible flat cable electrically connects to a connector.

### BRIEF DESCRIPTION OF THE DRAWINGS

FIG. 1 is a schematic three-dimensional view of a flexible flat cable according to a first preferred embodiment of the present invention;

FIG. 2 is a schematic exploded three-dimensional view of a partial flexible flat cable according to a first preferred embodiment of the present invention;

FIG. 3 is a schematic cross-sectional view of a main body section according to a first preferred embodiment of the present invention;

FIG. 4 is a schematic cross-sectional view of a contact section according to a first preferred embodiment of the present invention;

FIG. 5 is a schematic cross-sectional view of a main body section according to a second preferred embodiment of the present invention;

FIG. 6 is a schematic cross-sectional view of a contact section according to a second preferred embodiment of the present invention;

FIG. 7 is a schematic cross-sectional view of a main body section according to a third preferred embodiment of the present invention;

FIG. 8 is a schematic cross-sectional view of a contact section according to a third preferred embodiment of the present invention;

FIG. 9 is a schematic cross-sectional view of a main body section according to a fourth preferred embodiment of the present invention;

FIG. 10 is a schematic cross-sectional view of a main body section according to a fourth preferred embodiment of the present invention; and

FIG. 11 is a schematic view of a flexible flat cable connecting one FFC connector to the other FFC connector according to one preferred embodiment of the present invention.

### DETAILED DESCRIPTION OF THE PREFERRED EMBODIMENTS

The foregoing aspects and many of the attendant advantages of this invention will become more readily appreciated as the same becomes better understood by reference to the following detailed description but rather than limiting of the present invention.

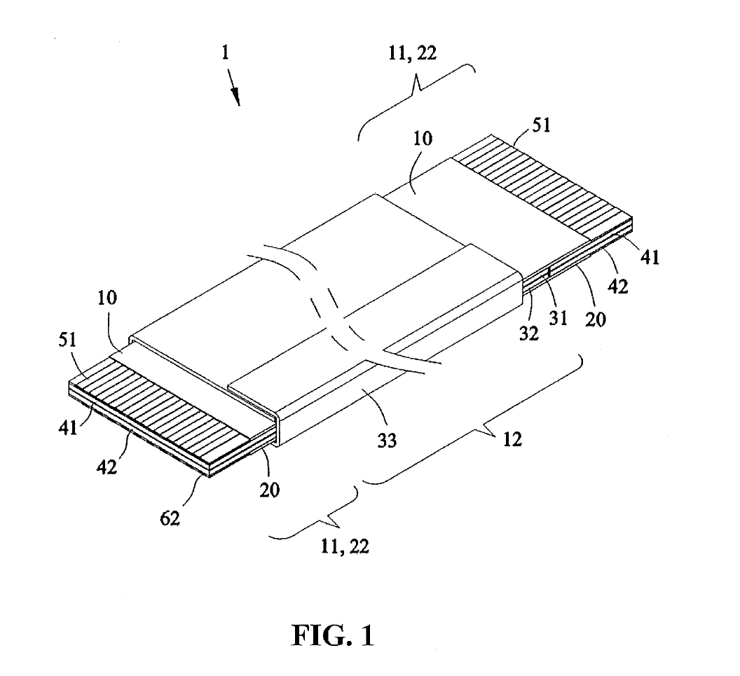

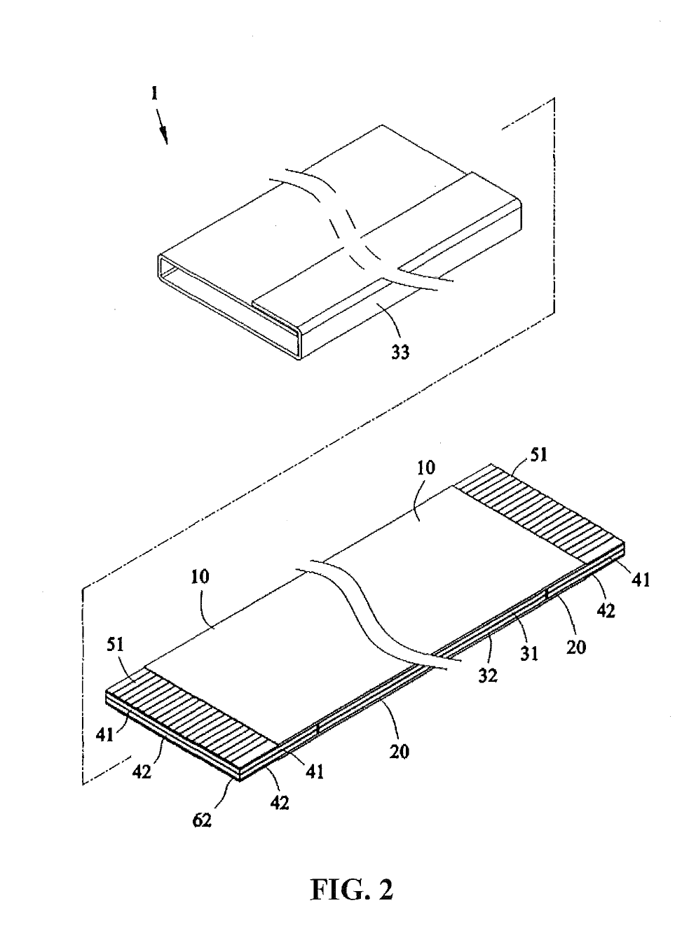

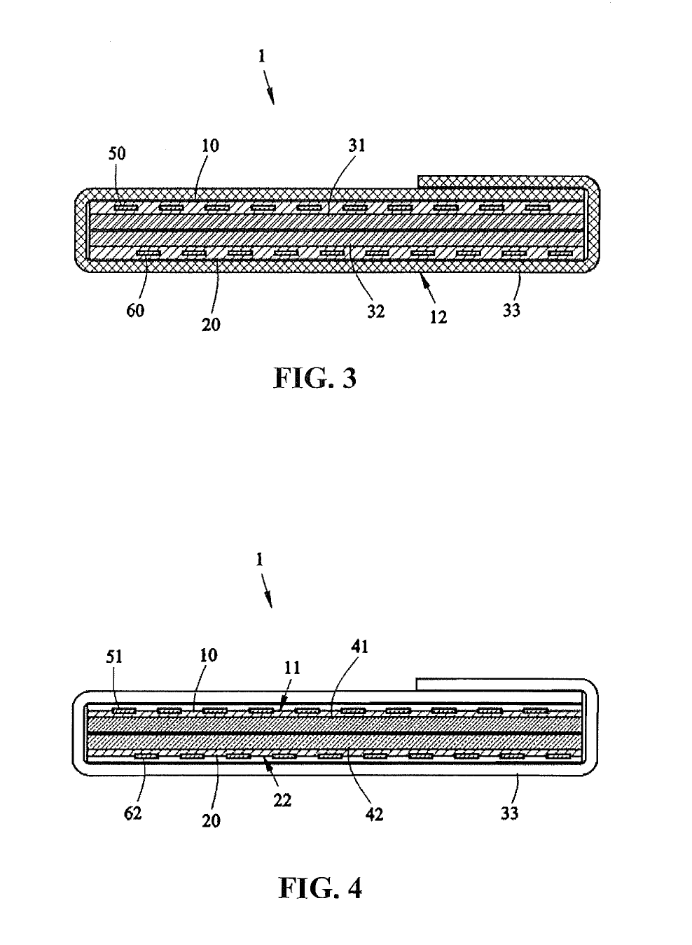

Referring to FIGS. 1-4, the flexible flat cable 1 in the present invention includes a first insulation layer 10, a second insulation layer 20, a first shielding layer 31 and a second shielding layer 32. The first insulation layer 10 covers a plurality of first conductors 50 and includes a first contact section 11 in the front end of the first insulation layer 10 wherein the first contact section 11 exposes a first contact surface region 51 of the first conductors 50. The second insulation layer 20 covers a plurality of second conductors 60 and includes a second contact section 22 in the front end of the second insulation layer 20 wherein the second contact section 22 exposes a second contact surface region 62 of second conductors 60. The first shielding layer 31 and second shielding layer 32 are disposed, for an example of a glue manner, between the first insulation layer 10 and second insulation layer 20. The first contact surface region 51 of the first conductors 50 is upwardly exposed from the first contact section 11 and the second contact surface region 62 of the second conductors 60 is downwardly exposed from the second contact section 22 so that flexible flat cable 1 is arranged in a dual-row manner to reduce the width of flexible flat cable 1 as a whole. Further, the first insulation layer 10, the first shielding layer 31, the second shielding layer 32 and the second insulation layer 20 are sequentially stacked to enhance the strength of the flexible flat cable 1. In one case, the first conductors 50 and the second conductors 60 are interlaced upward and downward, as show in FIG. 3 and FIG. 4, based on different high frequency characteristics. In another case, the first conductors 50 and the second conductors 60 are disposed correspondingly upward and downward (not shown) based on different high frequency characteristics.

Furthermore, the first insulation layer 10 includes another first contact section 11 in the rear end of the first insulation layer 10 wherein another first contact surface region 51 of the first conductors 50 is upwardly exposed from the first contact section 11 in the rear end of the first insulation layer 10. The second insulation layer 20 includes another second contact section 22 in the rear end of the second insulation layer 20 wherein a second contact surface region 62 of the second conductors 60 is downwardly exposed from the second contact section 22 in the rear end of the second insulation layer 20. In one embodiment, first shielding layer 31 and the second shielding layer 32 extend to the in-between position of the first contact section 11 and second contact section 22 to improve the construction strength and shielding effect of the flexible flat cable 1. In another embodiment, a first insulation supporting plate 41 and a second insulation supporting plate 42 are disposed in the in-between position of the first contact section 11 and second contact section 22 to improve the construction strength and shielding effect of the flexible flat cable 1. The material of first shielding layer 31 and second shielding layer 32 is selected from one group consisting of aluminum foil, polytetrafluoroethylene (Teflon), acetate cloth insulating tape and the material with electromagnetic shielding effect. A third shielding layer 33 further covers the outer surface of a main body section 12 and is the material selecting from one group consisting of aluminum foil, polytetrafluoroethylene (Teflon), acetate cloth insulating tape and the material with electromagnetic shielding effect.

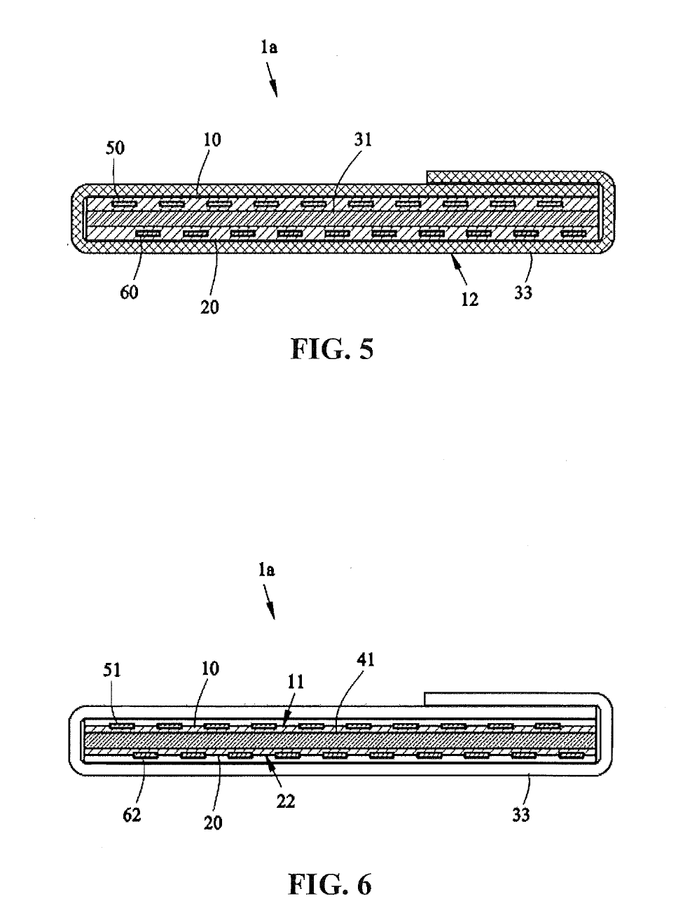

Referring to FIGS. 5 and 6, the flexible flat cable 1a in the second embodiment is substantially similar to the flexible flat cable 1 in the preferred embodiment. The difference is that only a first shielding layer 31 is disposed between the first insulation layer 10 and the second insulation layer 20 and only a first insulation supporting plate 41 is disposed between the first contact section 11 and second contact section 22 in the second embodiment of the present invention.

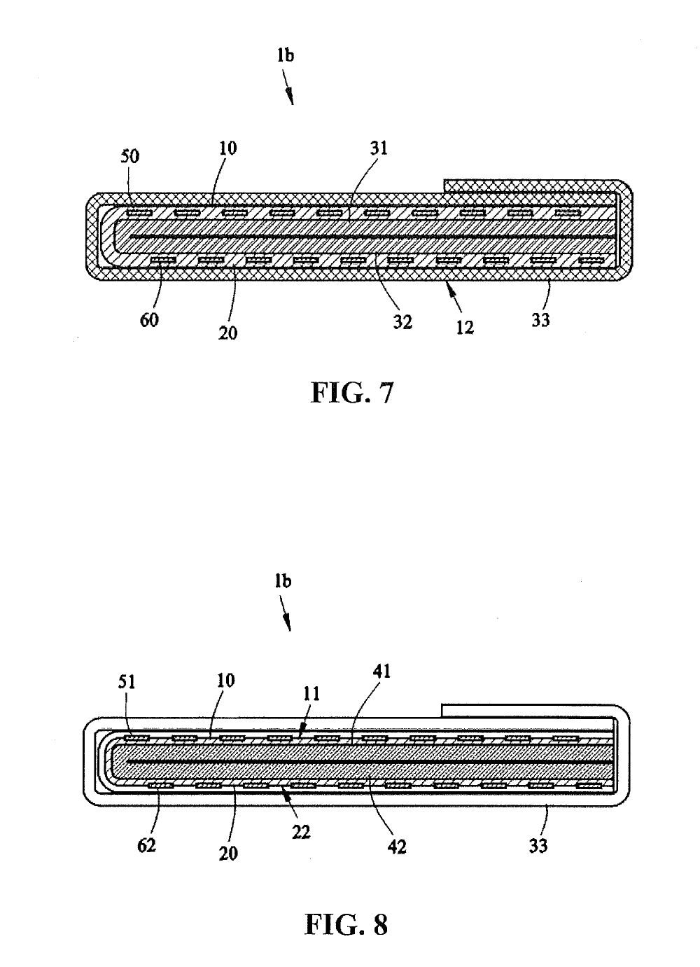

Referring to FIGS. 7 and 8, the flexible flat cable 1b in the third embodiment is substantially similar to the flexible flat cable 1 in the preferred embodiment. The difference is that the first insulation layer 10 and the second insulation layer 20 are formed by bending an identical insulation layer such that the first insulation layer 10, the first shielding layer 31 and the second insulation layer 20 sequentially stacked to form the flexible flat cable 1b. In one case, the first shielding layer 31 is formed by single layer structure and disposed, e.g. at a glue manner, between the first insulation layer 10 and second insulation layer 20. In another case, a dual-row structure including the first shielding layer 31 and the second shielding layer 32 is formed by bending a shielding layer and is disposed between the first insulation layer 10 and second insulation layer 20. Furthermore, in one embodiment, a first insulation supporting plate 41 is disposed between the first contact section 11 and the second contact section 22, or in another embodiment, a first insulation supporting plate 41 and a second insulation supporting plate 42 are disposed between the first contact section 11 and the second contact section 22. For example, a first insulation supporting plate 41 and a second insulation supporting plate 42 are formed by bending an identical insulation supporting plate. In one case, the first conductors 50 and the second conductors 60 are interlaced upward and downward, as show in FIGS. 7 and 8, based on different high frequency characteristics. In another case, the first conductors 50 and the second conductors 60 are disposed correspondingly upward and downward (not shown) based on different high frequency characteristics.

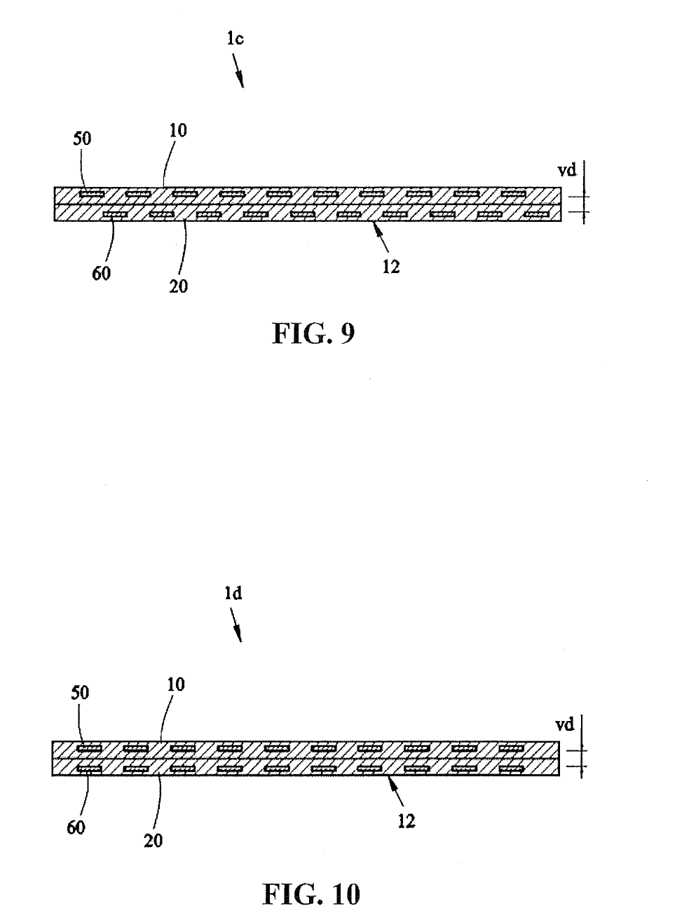

Referring to FIG. 9, the flexible flat cable 1c in the fourth embodiment is substantially similar to the flexible flat cable 1 in the preferred embodiment. The difference is that the flexible flat cable 1c is formed by sequentially stacking, e.g. at a glue manner, the first insulation layer 10 and the second insulation layer 20, wherein either the first insulation layer 10 and the second insulation layer 20 is an individual insulation layer respectively or the first insulation layer 10 and the second insulation layer 20 is formed, e.g. at a glue manner, by bending an identical insulation layer. For example, either a vertical distance “vd” from first conductors 50 to second conductors 60 is greater than twice the thickness of the first conductors 50, or the vertical distance “vd” from first conductors 50 to second conductors 60 is greater than the thickness of the second conductors 60. In one case, the first conductors 50 and the second conductors 60 are interlaced upward and downward to achieve the required high frequency characteristics.

Referring to FIG. 10, the flexible flat cable 1d in the fifth embodiment is substantially similar to the flexible flat cable 1 in the preferred embodiment. The difference is that the flexible flat cable 1d is formed by sequentially stacking, e.g. at a glue manner, the first insulation layer 10 and the second insulation layer 20, wherein the first insulation layer 10 and the second insulation layer 20 is an individual insulation layer respectively or the first insulation layer 10 and the second insulation layer 20 is formed, e.g. at a glue manner, by bending an identical insulation layer. For example, either a vertical distance “vd” from the first conductors 50 to second conductors 60 is greater than twice the thickness of the first conductors 50, or the vertical distance “vd” from the first conductors 50 to second conductors 60 is greater than the thickness of the second conductors 60. In another case, the first conductors 50 and the second conductors 60 are disposed correspondingly upward and downward to achieve the required high frequency characteristics.

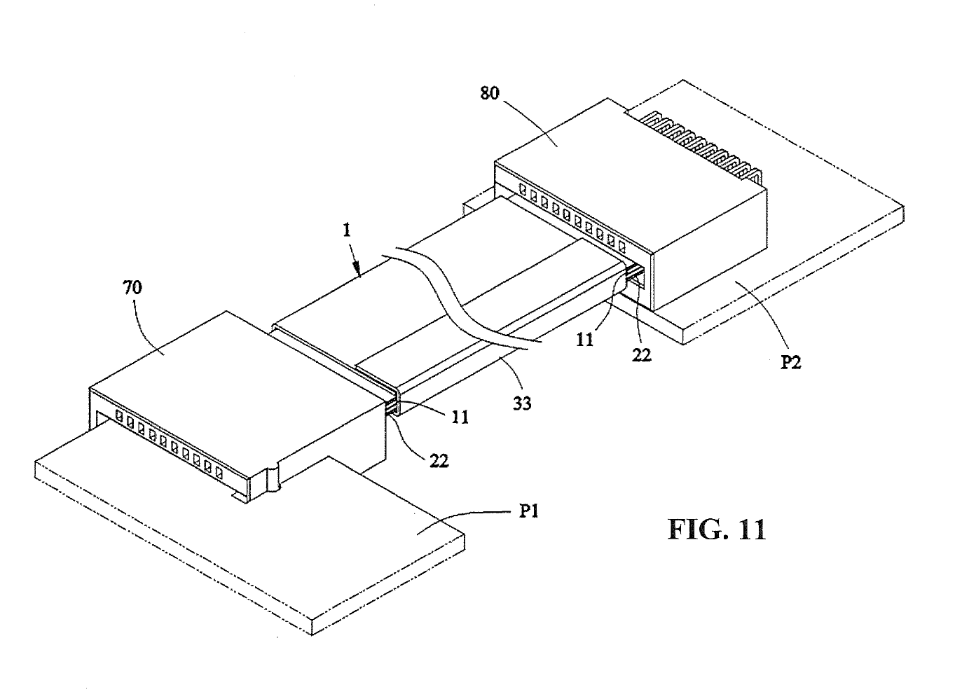

FIG. 11 is a schematic view of a flexible flat cable 1 connecting one FFC connector 70 to the other FFC connector 80 according to one preferred embodiment of the present invention. For example, the first contact section 11 and the second contact section in the front end and rear end of the flexible flat cable 1 are inserted to the one FFC connector 70 and the other FFC connector 80 respectively. The one FFC connector 70 electrically connects to circuit board P1 of electronic device, e.g. the circuit board of hard disk drive or storage device, but not limited, and the other FFC connector 80 electrically connects to another circuit board P2 of electronic device, e.g. the main circuit board of personal computer of notebook computer, but not limited. Additionally, the flexible flat cable 1 is capable of easily inserting to the one FFC connector 70 and the other FFC connector 80 and/or extracting from the one FFC connector 70 and the other FFC connector 80 advantageously.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A flexible flat cable, comprising:
a first insulation layer, covering a plurality of first conductors and comprising a first contact section in a front end of the first insulation layer wherein the first contact section exposes a first contact surface region of the first conductors;
a second insulation layer, covering a plurality of second conductors and comprising a second contact section in the front end of the second insulation layer wherein the second contact section exposes a second contact surface region of the second conductors; and
a first shielding layer disposed between the first insulation layer and the second insulation layer, wherein the first contact surface region of the first conductors is upwardly exposed from the first contact section and the second contact surface region of the second conductors is downwardly exposed from the second contact section.

2. The flexible flat cable of claim 1, wherein the first insulation layer comprises another first contact section in a rear end of the first insulation layer, another first contact surface region of the first conductors is upwardly exposed from the first contact section in the rear end of the first insulation layer, the second insulation layer comprises another second contact section in the rear end of the second insulation layer, and a second contact surface region of the second conductors is downwardly exposed from the second contact section in the rear end of the second insulation layer.

3. The flexible flat cable of claim 1, wherein the first shielding layer extends to an in-between position of the first contact section and the second contact section to improve construction strength and shielding effect of the flexible flat cable.

4. The flexible flat cable of claim 1, wherein a first insulation supporting plate is disposed in an in-between position of the first contact section and the second contact section to improve the construction strength and shielding effect of the flexible flat cable.

5. The flexible flat cable of claim 4, wherein a second insulation supporting plate is disposed in the in-between position of the first contact section and the second contact section to improve the construction strength and shielding effect of the flexible flat cable.

6. The flexible flat cable of claim 1, wherein a second shielding layer is disposed between the first shielding layer and the second insulation layer, and material of the first shielding layer and the second shielding layer is selected from one group consisting of aluminum foil, polytetrafluoroethylene (Teflon), acetate cloth insulating tape and material with electromagnetic shielding effect.

7. The flexible flat cable of claim 1, wherein a third shielding layer further covers an outer surface of a main body section of the flexible flat cable and is material selecting from one group consisting of aluminum foil, polytetrafluoroethylene (Teflon), acetate cloth insulating tape and the material with electromagnetic shielding effect.

8. The flexible flat cable of claim 1, wherein either the first conductors and the second conductors are interlaced upward and downward or the first conductors and the second conductors are disposed correspondingly upward and downward.

9. A flexible flat cable, comprising:
an insulation layer, for being bent to form a first insulation layer and a second insulation layer;
a plurality of first conductors, for covering the first insulation layer wherein a first contact surface region of the first conductors is exposed from a first contact section of the first insulation layer;
a plurality of second conductors, for covering the second insulation layer wherein a second contact surface region of the second conductors is exposed from the second contact section; and
a first shielding layer disposed between the first insulation layer and the second insulation layer, wherein the first contact surface region of the first conductors is upwardly exposed from the first contact section and the second contact surface region of the second conductors is downwardly exposed from the second contact section.

10. The flexible flat cable of claim 9, wherein the first insulation layer comprises another first contact section in a rear end of the first insulation layer, another first contact surface region of the first conductors is upwardly exposed from the first contact section in the rear end of the first insulation layer, the second insulation layer comprises another second contact section in the rear end of the second insulation layer, and a second contact surface region of the second conductors is downwardly exposed from the second contact section in the rear end of the second insulation layer.

11. The flexible flat cable of claim 9, wherein the first shielding layer extends to an in-between position of the first contact section and the second contact section to improve a construction strength and shielding effect of the flexible flat cable.

12. The flexible flat cable of claim 9, wherein a first insulation supporting plate is disposed in an in-between position of the first contact section and the second contact section to improve the construction strength and shielding effect of the flexible flat cable.

13. The flexible flat cable of claim 12, wherein a second insulation supporting plate is disposed in the in-between position of the first contact section and the second contact section, and the first insulation supporting plate and the second insulation supporting plate are formed by bending an identical insulation supporting plate.

14. The flexible flat cable of claim 9, wherein a second shielding layer is disposed between the first shielding layer and the second insulation layer, the first shielding layer and the second shielding layer are formed by bending an identical shielding layer, and material of the first shielding layer and the second shielding layer is selected from one group consisting of aluminum foil, polytetrafluoroethylene (Teflon), acetate cloth insulating tape and material with electromagnetic shielding effect.

15. The flexible flat cable of claim 9, wherein a third shielding layer further covers an outer surface of a main body section of the flexible flat cable and is material selecting from one group consisting of aluminum foil, polytetrafluoroethylene (Teflon), acetate cloth insulating tape and the material with electromagnetic shielding effect.

16. The flexible flat cable of claim 9, wherein either the first conductors and the second conductors are interlaced upward and downward or the first conductors and the second conductors are disposed correspondingly upward and downward.

17. A flexible flat cable, comprising:
a first insulation layer, covering a plurality of first conductors and comprising a first contact section in a front end of the first insulation layer wherein the first contact section exposes a first contact surface region of the first conductors; and
a second insulation layer, covering a plurality of second conductors and comprising a second contact section in the front end of the second insulation layer, wherein the second contact section exposes a second contact surface region of the second conductors;
wherein the first contact surface region of the first conductors is upwardly exposed from the first contact section, and the second contact surface region of the second conductors is downwardly exposed from the second contact section; and
wherein a vertical distance between the first conductors and the second conductors is greater than twice a thickness of either the first conductor or the second conductor.

18. The flexible flat cable of claim 17, wherein the first insulation layer comprises another first contact section in a rear end of the first insulation layer, another first contact surface region of the first conductors is upwardly exposed from the first contact section in the rear end of the first insulation layer, the second insulation layer comprises another second contact section in the rear end of the second insulation layer, and a second contact surface region of the second conductors is downwardly exposed from the second contact section in the rear end of the second insulation layer.

19. The flexible flat cable of claim 17, wherein the first insulation layer is glued to the second insulation layer, and the first insulation layer and the second insulation layer are an individual insulation layer respectively.

20. The flexible flat cable of claim 17, wherein the first conductors and the second conductors are interlaced upward and downward or the first conductors and the second conductors are disposed correspondingly upward and downward.
